(19) United States
(12) Patent Application Publication
(10) Pub. No.: US 2013/0049118 A1
(43) Pub. Date: Feb. 28, 2013

(54) THIN-FILM TRANSISTOR AND METHOD OF MANUFACTURING THE SAME, AND ELECTRONIC UNIT

(71) Applicant: Mao Katsuhara, Kanagawa (JP)

(72) Inventor: Mao Katsuhara, Kanagawa (JP)

(73) Assignee: SONY CORPORATION, Tokyo (JP)

(21) Appl. No.: 13/587,145

(22) Filed: Aug. 16, 2012

(30) Foreign Application Priority Data
Aug. 25, 2011 (JP) 2011-183986

(51) Int. Cl. H01L 51/10; H01L 29/786; H01L 21/336

(52) U.S. Cl. 257/347; 438/151; 257/E29.273; 257/E21.409; 257/E51.005

(57) ABSTRACT

There are provided a thin-film transistor that leads to the improved performance and production stability, and a method of manufacturing the thin-film transistor, and an electronic unit using the thin-film transistor. The thin-film transistor includes: an organic semiconductor section including first and second surfaces; a source electrode section adjacent to the first surface; and a drain electrode section adjacent to the second surface. One or both of the source electrode section and the drain electrode section are highly-conductive electrode sections containing an organic semiconductor material higher in conductivity than a material of the organic semiconductor section.

### BACKGROUND

The present technology relates to a thin-film transistor including an organic semiconductor section, a source electrode section, and a drain electrode section, a method of manufacturing the thin-film transistor, and an electronic unit using the thin-film transistor.

In recent years, various electronic units use a thin-film transistor (TFT) as a switching device or others. As the TFT, an organic TFT using an organic semiconductor material for forming a semiconductor layer (channel layer) has been recently considered as a promising alternative to an inorganic TFT using an inorganic semiconductor material therefor. This is since, with the organic TFT, the semiconductor layer is able to be formed by coating so that the cost reduction is achievable. Also with the organic TFT, the semiconductor layer is able to be formed at a temperature lower than that for vapor deposition or others, thereby allowing the use of a low-heat-resistant flexible plastic film or others as a support base.

The organic TFT includes, on a support base, an organic semiconductor layer, a source electrode, and a drain electrode. The organic semiconductor layer is provided away from a gate electrode via a gate insulating layer, and the source electrode and the drain electrode are connected to the organic semiconductor layer.

The organic TFT is known to be in the top-contact structure and the bottom-contact structure. In the top-contact structure, the source electrode and the drain electrode are overlaid on the upper side of the organic semiconductor layer, and in the bottom-contact structure, the source electrode and the drain electrode are overlaid on the lower side of the organic semiconductor layer (for example, see Non-Patent Literature 1 (Advanced Materials vol. 14, p. 99 (2002), C. D. Dimitrakopoulos et al.)). Between these two structures, the bottom-contact structure is generally widely used since the source electrode and the drain electrode are allowed to be formed by high-precision patterning using photolithography.

Other than those structures, the organic TFT is known to be in the bottom-gate structure, and in the top-gate structure. In the bottom-gate structure, the gate electrode is placed on the lower side of the organic semiconductor layer (on the side closer to the support base), and in the top-gate structure, the gate electrode is placed on the upper side of the organic semiconductor layer (on the side away from the support base).

In manufacturing the organic TFT, a connection is expected to be established without fail between the organic semiconductor layer, and the source electrode and the drain electrode in order to reserve a current path. In consideration thereof, previously proposed is to form the source electrode and the drain electrode by photolithography, lift-off, or others, and to exert control with a high precision over positions of the electrodes (for example, see Japanese Unexamined Patent Application Publication Nos. 2008-053582, 2006-286719, and 2006-165555).

### SUMMARY

In the organic semiconductor layer, an active region substantially in charge of charge transport is known to be a very restricted region corresponding to the thickness of a layer of several molecules (about 10 nm or less) from the interface between the gate insulating layer and the organic semiconductor layer (for example, see Non-patent Document 1). As such, to manufacture a high-performance organic TFT with a good stability, the production stability is expected to be improved by reducing the performance variations among a plurality of organic TFTs at the same time with an attempt to improve the performance thereof by utilizing the active region as a current path.

In this respect, with the organic TFT in the bottom-contact structure, the source electrode and the drain electrode are connected to the active region so that the contact resistance is reduced. However, the positioning between these electrodes and the organic semiconductor layer is difficult, and this easily causes the performance to vary among a plurality of organic TFTs. In the organic TFT in the top-contact structure, on the other hand, the positioning described above is also difficult, and the source electrode and the drain electrode are not connected to the active region. This thus increases the contact resistance due to the high resistance existing between these electrodes and the active region.

It is thus desirable to provide a thin-film transistor that leads to the improved performance and production stability, and a method of manufacturing the thin-film transistor, and an electronic unit.

According to an embodiment of the present technology, there is provided thin-film transistor, including: an organic semiconductor section including first and second surfaces; a source electrode section adjacent to the first surface; and a drain electrode section adjacent to the second surface. One or both of the source electrode section and the drain electrode section are highly-conductive electrode sections containing an organic semiconductor material higher in conductivity than a material of the organic semiconductor section.

Moreover, according to an embodiment of the present technology, there is provided an electronic unit including a thin-film transistor, the thin-film transistor including: an organic semiconductor section including first and second surfaces; a source electrode section adjacent to the first surface; and a drain electrode section adjacent to the second surface. One or both of the source electrode section and the drain electrode section are highly-conductive electrode sections containing an organic semiconductor material higher in conductivity than a material of the organic semiconductor section.

According to an embodiment of the present technology, there is provided a method of manufacturing a thin-film transistor, including: forming an organic semiconductor layer; forming an organic semiconductor section by an addition of an impurity to a part of the organic semiconductor layer for increasing conductivity, and forming one or both of a source electrode section and a drain electrode section, the organic semiconductor section including first and second surfaces, the source electrode section being adjacent to the first surface, and the drain electrode section being adjacent to the second surface; and using one or both of the source electrode section and the drain electrode section as highly-conductive electrode sections, the highly-conductive electrode section containing an organic semiconductor material higher in conductivity than a material of the organic semiconductor section.

Moreover, according to another embodiment of the present technology, there is provided a method of manufacturing a thin-film transistor, including: forming an organic semiconductor section including a first surface and a second surface; and forming one or both of a source electrode section and a drain electrode section using an organic semiconductor material higher in conductivity than a material of the organic semiconductor section, the source electrode section being adjacent to the first surface, and the drain electrode section being adjacent to the second surface.

With the thin-film transistor or the manufacturing method thereof, or an electronic unit according to the embodiments of the present technology, one or both of the source electrode section and the drain electrode section adjacent to the organic semiconductor section are highly-conductive electrode sections, which each contain the organic semiconductor material higher in conductivity than the material of the organic semiconductor section. This accordingly leads to the improved performance and production stability.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional diagram showing the configuration of a thin-film transistor according to a first embodiment of the present technology.

FIG. 2 is a cross-sectional diagram showing another configuration of the thin-film transistor.

FIG. 3 is a cross-sectional diagram showing still another configuration of the thin-film transistor.

FIG. 4 is a cross-sectional diagram for illustrating a method of manufacturing the thin-film transistor according to the first embodiment of the present technology.

FIG. 5 is a cross-sectional diagram for illustrating a process subsequent to that of FIG. 4.

FIG. 6 is a cross-sectional diagram for illustrating a process subsequent to that of FIG. 5.

FIG. 7 is a cross-sectional diagram showing the configuration of a thin-film transistor according to a second embodiment of the present technology.

FIG. 8 is a cross-sectional diagram showing another configuration of the thin-film transistor.

FIG. 9 is a cross-sectional diagram showing still another configuration of the thin-film transistor.

FIG. 10 is a cross-sectional diagram for illustrating a method of manufacturing the thin-film transistor according to the second embodiment of the present technology.

FIG. 11 is a cross-sectional diagram for illustrating a process subsequent to that of FIG. 10.

FIG. 12 is a cross-sectional diagram for illustrating a process subsequent to that of FIG. 11.

FIG. 13 is a cross-sectional diagram for illustrating a process subsequent to that of FIG. 12.

FIG. 14 is a cross-sectional diagram showing the configuration of a thin-film transistor according to a modification example.

FIG. 15 is a cross-sectional diagram showing the configuration of a thin-film transistor according to another modification example.

FIG. 16 is a cross-sectional diagram showing the configuration of a liquid crystal display, which is an application example of the thin-film transistors according to the embodiments of the present technology.

FIG. 17 is a circuit diagram of the liquid crystal display of FIG. 16.

FIG. 18 is a cross-sectional diagram showing the configuration of an organic electroluminescent (EL) display, which is an application example of the thin-film transistor.

FIG. 19 is a circuit diagram of the organic EL display of FIG. 18.

FIG. 20 is a cross-sectional diagram showing the configuration of an electronic paper display, which is an application example of the thin-film transistor.

### DETAILED DESCRIPTION

In the below, embodiments of the present technology are described in detail by referring to the accompanying drawings. The description is given in the following order.

1. First Embodiment
1-1. Configuration of Thin-Film Transistor
1-2. Method of Manufacturing Thin-Film Transistor

2. Second Embodiment
2-1. Configuration of Thin-Film Transistor
2-2. Method of Manufacturing Thin-Film Transistor

3. Modification Examples

4. Application Examples of Thin-Film Transistor (Electronic Units)
4-1. Liquid Crystal Display
4-2. Organic EL Display
4-3. Electronic Paper Display

### 1. FIRST EMBODIMENT/1-1. CONFIGURATION OF THIN-FILM TRANSISTOR

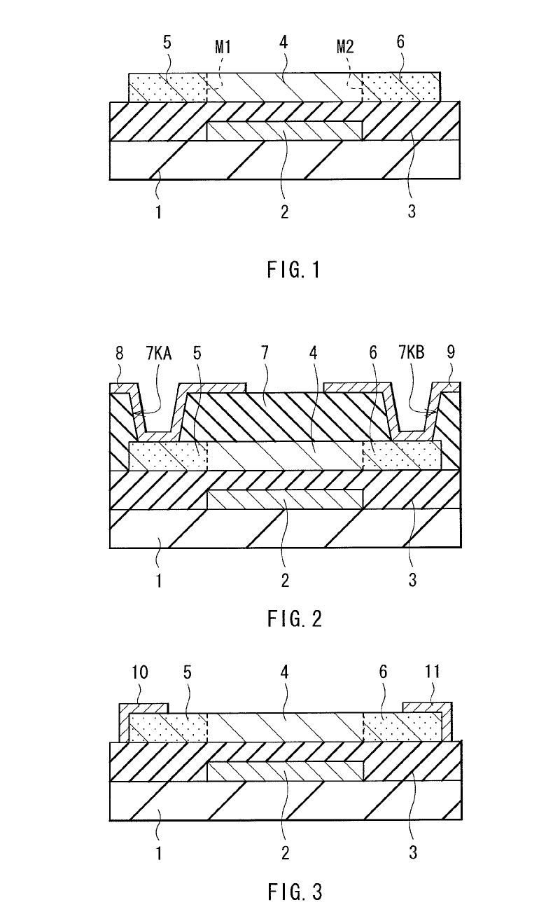

First of all, described is the configuration of a thin-film transistor according to a first embodiment of the present technology. FIG. 1 is a diagram showing the cross-sectional configuration of a thin-film transistor (organic TFT) including an organic semiconductor section 4 as a channel layer.

This organic TFT includes, on a support base 1, a gate electrode 2, a gate insulating layer 3, an organic semiconductor section 4, a source electrode section 5, and a drain electrode section 6, for example. This organic semiconductor section 4 is provided with two surfaces (first and second surfaces). The source electrode section 5 is adjacent to the first surface, and the drain electrode section 6 is adjacent to the second surface. In this example, the two surfaces are a pair of side surfaces M1 and M2, and the source electrode section 5 and the drain electrode section 6 are adjacent to the side surfaces M1 and M2, respectively.

To be more specific, the organic TFT of FIG. 1 is neither in the top-contact structure nor in the bottom-contact structure, but is in the coplanar homojunction structure, for example. In the coplanar homojunction structure, the source electrode section 5 and the drain electrode section 6 are provided in the same hierarchy level as the organic semiconductor section 4. Note that, FIG. 1 shows the organic TFT in the bottom-gate structure in which the gate electrode 2 is located on the lower side (the side closer to the support base 1) of the organic semiconductor section 4, for example.

The support base 1 is made of one or two or more of a plastic material, a metal material, and an inorganic material, for example.

The plastic material is exemplified by polymethyl methacrylate (PMMA), polyvinyl alcohol (PVA), polyvinyl phenol (PVP), poly ether sulphone (PES), polycarbonate (PC), polyimide (PI), polyethylene terephthalate (PET), polyethylene naphthalate (PEN), polyether ether ketone (PEEK), polyacrylate (PAR), polyphenylene sulfide (PPS), or triacetylcellulose (TAC). The metal material is exemplified by aluminum (Al), nickel (Ni), or stainless steel. The inorganic material is exemplified by silicon (Si), silicon oxide (SiOₓ), silicon nitride (SiNₓ), aluminum oxide (AlOₓ), or any other metal oxides. Herein, the silicon oxide includes glass, quartz, spin-on glass (SOG), or others.

This support base 1 may be a substrate with rigidity such as wafer, or a film or foil with flexibility, for example. Moreover, on the surface of the support base 1, a coating layer with predetermined functions may be provided. This coating layer is exemplified by a buffer layer for ensuring a high degree of adhesion, or a gas barrier layer for preventing emission of gas.

Herein, the support base 1 may be in the single-layer structure or the multi-layer structure. When being in the multi-layer structure, the support base 1 includes two or more layers each made of any of the various materials described above. The support base 1 allowed to be in the single-layer structure or the multi-layer structure as such is applicable also to the other components, i.e., the gate electrode 2, the gate insulating layer 3, the organic semiconductor section 4, the source electrode section 5, and the drain electrode section 6.

The gate electrode 2 is formed on the support base 1, and is provided to be away from the organic semiconductor section 4, the source electrode section 5, and the drain electrode section 6, via the gate insulating layer 3. This gate electrode 2 contains one or two or more of a metal material, an inorganic conductive material, an organic conductive material, and a carbon material, for example.

The metal material is exemplified by aluminum, copper (Cu), molybdenum (Mo), titanium (Ti), chromium (Cr), nickel, palladium (Pd), gold (Au), silver (Ag), platinum (Pt), tungsten (W), tantalum (Ta), or an alloy thereof The inorganic conductive material is exemplified by indium oxide (In₂O₃), indium tin oxide (ITO), indium zinc oxide (IZO), or zinc oxide (ZnO). The organic conductive material is exemplified by polyethylenedioxythiophene (PEDOT), polystyrenesulfonate (PSS), or polyaniline (PANT). The carbon material is exemplified by graphite. Note here that the gate electrode 2 may be in the multi-layer structure such as PEDOT/PSS.

The gate insulating layer 3 is so formed as to cover at least the gate electrode 2, and contains one or two or more of an inorganic insulating material, an organic insulating material, and others. The inorganic insulating material is exemplified by silicon oxide, silicon nitride, aluminum oxide, titanium oxide (TiO₂), hafnium oxide (HfOₓ), or barium titanate (BaTiO₃). The organic insulating material is exemplified by polyvinyl phenol (PVP), polyvinyl alcohol (PVA), polyimide, polyamide, polyester, polyacrylate, poly(acrylete-methacrylate), epoxy resin, benzocyclobutene (BCB), fluorocarbon polymer, photosensitive polyimide, photosensitive novolac resin, or poly-para-xylylene.

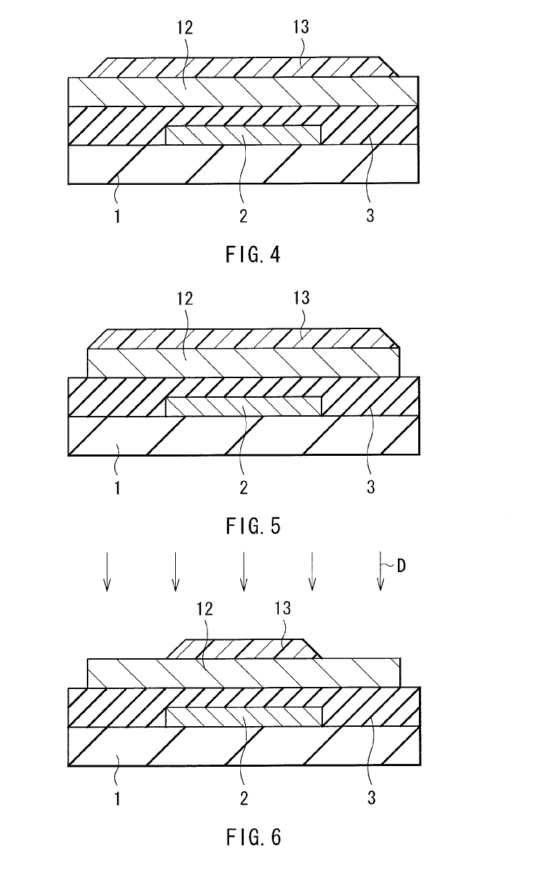

The organic semiconductor section 4 is formed on the gate insulating layer 3, and is integral with one or both of the source electrode section 5 and the drain electrode section 6. This is since the organic semiconductor section 4 is a portion left as it is after a doping process performed to a part of an organic semiconductor layer 12 being a preprocessing layer (see FIGS. 4 to 6) as will be described later. In other words, the organic semiconductor section 4 is a part of the organic semiconductor layer 12 not subjected to the doping process. On the other hand, the portion of the organic semiconductor layer 12 subjected to the doping process serves as one or both of the source electrode section 5 and the drain electrode section 6.

In this example, the source electrode section 5 and the drain electrode section 6 are both formed by the doping process performed to the organic semiconductor layer 12. The organic semiconductor section 4 is thus integral with both of the source electrode section 5 and the drain electrode section 6. With such a configuration, the pair of side surfaces M1 and M2 described above are not surfaces (interfaces or junction surfaces) where the organic semiconductor section 4 is in contact with the source electrode section 5 and the drain electrode section 6 if these are physically separated from each other. In other words, the side surfaces M1 and M2 are surfaces (virtual surfaces) that partition the organic semiconductor layer 12 formally according to the composition thereof (whether the doping process has been performed thereto or not). In this configuration, the organic semiconductor section 4 is preferably opposed to at least the gate electrode 2.

The organic semiconductor section 4 contains one or two or more of the following organic semiconductor materials (hereinafter, referred to as “channel-use organic semiconductor materials”): (1) polypyrrole, (2) polythiophene, (3) isothianaphthene such as polyisothianaphthene, (4) thienylene vinylene such as polythienylene vinylene, (5) poly(p-phenylenevinylene) such as poly(p-phenylenevinylene), (6) polyaniline, (7) polyacetylene, (8) polydiacetylene, (9) polyazulene, (10) polypyrene, (11) polycarbazole, (12) polyselenophene, (13) polyfuran, (14) poly(p-phenylene), (15) polyindole, (16) polypyridazine, (17) acene such as naphthacene, pentacene, hexacene, heptacene, dibenzo pentacene, tetrabenzo pentacene, pyrene, dibenzo pyrene, chrysene, perylene, coronene, terylene, ovalene, quaterrylene, and circumanthracene, (18) derivatives such as triphenodioxazine, triphenodithiazine, or hexacene-6,15-quinone, wherein a part of carbon contained in acene group is substituted by atom such as nitrogen (N), sulfur (S), or oxygen (O), or a functional group including carbonyl group, (19) polymeric materials such as polyvinyl carbazole, polyphenylene sulfide, or polyvinylene sulfide, and polycyclic condensed compounds, (20) oligomers with repeating units same as those in the polymeric materials described above, (21) metal phthalocyanine such as copper phthalocyanine, (22) tetrathiafulvalene, (23) tetrathiapentalene, (24) with naphthalene 1,4,5,8-tetracarboxylic diimide, N,N′-bis(4-trifluoromethyl benzyl)naphthalene 1,4,5,8-tetracarboxylic diimide, N,N′-bis(1H,1H-perfluorooctyl), N,N′-bis(1H,1H-perfluorobutyl), or N,N′-dioctyl-naphthalene 1,4,5,8-tetracarboxylic diimide derivatives, (25) naphthalene tetracarboxylic diimide such as naphthalene 2,3,6,7 tetracarboxylic diimide, (26) fused-ring tetracarboxylic diimide typified by anthracene tetracarboxylic diimides such as anthracene 2,3,6,7-tetracarboxylic diimide, (27) fullerene such as C₆₀, C₇₀, C₇₆, C₇₈, or C₈₄, (28) carbon nanotube such as single-walled nanotube (SWNT), (29) pigment such as merocyanine pigment and hemicyanine pigment, and (30) peri-xanthenoxanthene compounds such as 2,9-dinaphthyl peri-xanthenoxanthene.

Other than these, the channel-use organic semiconductor materials may be derivatives of the materials described above. The derivatives are the materials containing one or two or more of substituents in the materials described above. The types of the substituents, the positions therefor, and others are arbitrary.

The source electrode section 5 and the drain electrode section 6 are provided in the space (hierarchy level) on the gate insulating layer 3, for example. This space is defined by the thickness of the organic semiconductor section 4. Accordingly, as described above, the source electrode section 5 is adjacent to the side surface M1 of the organic semiconductor section 4, and the drain electrode section 6 is adjacent to the remaining side surface M2 thereof. In this case, as exemplarily shown in FIG. 1, the upper surface of the source electrode section 5 and that of the drain electrode section 6 are in-plane with the upper surface of the organic semiconductor section 4. In other words, the organic semiconductor section 4, and the source electrode section 5, and the drain electrode section 6 are all made flat to be in-plane.

These source electrode section 5 and the drain electrode section 6 are both integral with the organic semiconductor section 4 as described above, and are a doped part of the organic semiconductor layer 12 (see FIGS. 4 to 6), for example. Note that the hatched portion of FIG. 1 indicates that the source electrode section 5 and the drain electrode section 6 are formed by the doping process.

The source electrode section 5 and the drain electrode section 6 are both highly-conductive electrode sections containing an organic semiconductor material higher in conductivity than the material of the organic semiconductor section 4, for example. Hereinafter, such a material is referred to as “electrode-use organic semiconductor material”. Accordingly, the highly-conductive electrode sections, i.e., the source electrode section 5 and the drain electrode section 6, and the organic semiconductor layer 4 are formed as layers in the same hierarchy level as described above, for example. Moreover, the interfaces of these components formed as layers in the same hierarchy level as such, i.e., the organic semiconductor section 4, and the source electrode section 5 and the drain electrode section 6, with the gate insulating layer 3 are in one plane, for example.

As described above, the electrode-use organic semiconductor material is a channel-use organic semiconductor material added (doped) with an impurity (dopant) for increasing the conductivity. This dopant is one or two or more of the materials below, for example.

When the channel-use organic semiconductor material is of a p-type, the dopant for use is an acceptor material. This acceptor material is a metal oxide, a metal halide, a halide, a carbonate, or an organic material, for example.

The metal oxide is exemplified by molybdenum oxide (MoOₓ), rhenium oxide (ReO₃), vanadium oxide (V₂O₅), tungsten oxide (WO₃), titanium oxide (TiO₂), gold oxide (AuO), aluminum oxide (Al₂O₃), or copper oxide (CuO). The metal halide is exemplified by copper iodide (CuI), antimony chloride (SbCl₅), antimony fluoride (SbF₅), iron chloride (FeCl₃), lithium fluoride (LiF), barium fluoride (BaF₂), calcium fluoride (CaF₂), or magnesium fluoride (MgF₂). The halide is exemplified by arsenic fluoride (AsF₅), boron fluoride (BF₃), boron chloride (BCl₃), boron bromide (BBr₃), or phosphorus fluoride (PF₅). The carbonate is exemplified by calcium carbonate (CaCO₃), barium carbonate (BaCO₃), or lithium carbonate (Li₂CO₃).

The organic material is exemplified by p-benzoquinones, diphenoquinones, tetracyanoquinodimethanes (TCNQ), fluorenes, benzocyanos, or transition metal complexes.

The p-benzoquinones include 2,3,5,6-tetracyano-(p-cyanyl), 2,3-dibromo-5,6-dicyano-p-benzoquinone, 2,3-dichloro-5,6-dicyano-p-benzoquinone, 2,3-diiodo-5,6-dicyano-p-benzoquinone, 2,3-dicyano-p-benzoquinone, p-bromanil, p-chloranil, p-yodenil, p-fluoranil, 2,5-dichloro-p-benzoquinone, 2,6-dichloro-p-benzoquinone, chloranilic acid, bromanilic acid, 2,5-dihydroxy-p-benzoquinone, 2,5-dichloro-3,6-dimethyl-p-benzoquinone, 2,5-dibromo-3,6-dimethyl-p-benzoquinone, p-benzoquinone, 2,5-dimethyl-p-benzoquinone, 2,6-dimethyl-p-benzoquinone, duro(tetramethyl), o-benzoquinones, o-bromanil, o-chloranil, 1,4-naphthoquinones, 2,3-dicyano-5-nitro-1,4-naphthoquinone, 2-3-dicyano-1,4-naphthoquinone, 2,3-dichloro-5-nitro-1,4-naphthoquinone, 2,3-dichloro-1,4-naphthoquinone, 1,4-naphthoquinone, 9,10-anthraquinone, or others.

The diphenoquinones include 3,3′,5,5′-tetrabromo-diphenoquinone, 3,3′,5,5′-tetrachloro-diphenoquinone, diphenoquinone, or others. The TCNQs include TCNQ, tetrafluoro-tetracyano-quinodimethane (F4-TCNQ), trifluoromethyl-TCNQ, 2,5-difluoro-TCNQ, monofluoro-TCNQ, TNAP, decyl-TCNQ, methyl-TCNQ, dihydrobarreleno-TCNQ, tetrahydrobarreleno-TCNQ, dimethyl-TCNQ, diethyl-TCNQ, benzo-TCNQ, dimethoxy-TCNQ, BTDA-TCNQ, diethoxy-TCNQ, tetramethyl-TCNQ, tetracyano-anthraquinodimethane, poly-nitro compound, tetranitro-biphenol, dinitrobiphenyl, picric acid, trinitrobenzene, 2,6-dinitrophenol, 2,4-dinitrophenol, or others.

The fluorenes include 9-dicyanomethylene-2,4,5,7-tetranitro-fluoren, 9-dicyanomethylene-2,4,7-trinitro-fluorene, 2,4,5,7-tetoranitro-fluorenone, 2,4,7-trinitro-fluorenone, or others.

The benzocyanos include (TBA)₂HCTMM, (TBA)₂HCDAHD, K.CF, TBA.PCA, TBA.MeOTCA, TBA.EtOTCA, TBA.PrOTCA, (TBA)₂HCP, hexacyanobutadiene-tetracyanoethylene, 1,2,4,5-tetracyanobenzene, or others. Herein, “TBA” denotes tetrabutylammonium.

The transition metal complexes include (TPP)₂Pd(dithiooxalate)₂, (TPP)₂Pt(dithiooxalate)₂, (TPP)₂Ni(dithiooxalate)₂, (TPP)₂Cu(dithiooxalate)₂, (TBA)₂Cu(oxalate)₂, or others. Herein, “TPP” denotes tetraphenylphosphonium.

When the channel-use organic semiconductor material is of an n-type, the dopant for use is a donor material. This donor material is exemplified by alkali metal, metal carboxylate, aromatic hydrocarbon, TFFs, azines, monoamines, or diamines

The alkali metal includes lithium (Li), sodium (Na), cesium (Cs), or others. The metal carboxylate includes cesium carbonate (Cₛ₂CO₃), rubidium carbonate (Rb₂CO₃), or others. The aromatic hydrocarbon includes tetracene, perylene, anthracene, coronene, pentacene, chrysene, phenanthrene, naphthalene, p-dimethoxybenzene, rubrene, hexamethoxytriphenylene, or others.

The TFTs include HMTTF, OMTTF, TMTTF, BEDO-TTF, TTeCn-TTF, TMTSF, EDO-TTF, HMTSF, TTF, EOET-TTF, EDT-TTF, (EDO)₂DBTTF, TSCn-TTF, HMTTeF, BEDT-TTF, CnTET-TTF, TTCn-TTF, TSF, DBTTF, or others. Other than these, the TTTs include tetrathiotetracene, tetraselenotetracene, tetratellurotetracene, or others.

The azines include dibenzo[c,d]-phenothiazine, benzo[c]-phenothiazine, phenothiazine, N-methyl-phenothiazine, dibenzo[c,d]-phenoselenazine, N,N-dimethylphenazine, phenazine, or others.

The monoamines include N,N-diethyl-m-toluidine, N,N-diethylaniline, N-ethyl-o-toluidine, diphenylamine, skatole, indole, N,N-dimethyl-o-toluidine, o-toluidine, m-toluidine, aniline, o-chloroaniline, o-bromoaniline, or p-nitroaniline, or others.

The diamines include N,N,N′,N′-tetramethyl-p-phenylenediamine, 2,3,5,6-tetramethyl-(durenediamine), p-phenyldiamine, N,N,N′,N′-tetoramethylbenzidine, 3,3′,5,5′-tetoramethylbenzidine, 3,3′-dimethylbenzidine, 3,3′-dimethoxybenzidine, benzidine, 3,3′-dibromo-5,5′-dimethylbenzidine, 3,3′-dichloro-5,5′-dimethylbenzidine, 1,6-diaminopyrene, or others.

Other than these, exemplified are 4,4′,4″-tris(N-3-methylphenyl-N-phenylamino)-triphenylamine (m-MTDATA), 4,4′,4″-tris(N-(2-naphthyl)-N-phenylamino)-triphenylamine (2TNATA), u-NDP, copper phthalocyanine, 1,4,6,8-tetrakisdimethyl aminopyrene, 1,6-dithiopyren, decamethylferrocene, ferrocene, or others.

Note that described above is the case where the source electrode section 5 and the drain electrode section 6 are both formed by the doping process performed to the organic semiconductor layer 12, but this is not necessarily restrictive. Alternatively, one of the source electrode section 5 and the drain electrode section 6 may be formed by the doping process performed to the organic semiconductor layer 12, for example. The remaining of the source electrode section 5 and the drain electrode section 6 not formed by the doping process performed to the organic semiconductor layer 12 may contain the material similar to that of the gate electrode 2, and may be formed separately from the organic semiconductor section 4, for example. In this case, the source electrode section 5 or the drain electrode section 6 may be adjacent to the side surface M1 or M2 of the organic semiconductor section 4, or may be overlaid on the upper or lower side of the organic semiconductor section 4.

In this example, the organic TFT may be provided with any other component not described above if appropriate. FIGS. 2 and 3 each show another configuration of the organic TFT, and show the cross-sectional configuration thereof corresponding to FIG. 1.

The organic TFT of FIG. 2 is in the configuration similar to that of the organic TFT of FIG. 1 except that the organic TFT of FIG. 2 additionally includes a inter-layer insulating layer 7, and wiring patterns 8 and 9. The wiring patterns 8 and 9 are formed on the inter-layer insulating layer 7, and are separated from each other. The inter-layer insulating layer 7 is so formed as to cover the organic semiconductor layer 4, the source electrode section 5 and the drain electrode section 6, and others. The inter-layer insulating layer 7 contains the material similar to that of the gate insulating layer 3 (for example, PVP), for example. The wiring pattern 8 is connected to the upper surface of the source electrode section 5 through an aperture section 7KA, which is formed to the inter-layer insulating layer 7, for example. The wiring pattern 9 is connected to the upper surface of the drain electrode section 6 through an aperture section 7KB, which is formed to the inter-layer insulating layer 7, for example. These wiring patterns 8 and 9 each contain the material similar to that of the gate electrode 2, for example. To be more specific, the wiring patterns 8 and 9 each contain a metal material including copper, aluminum, titanium, molybdenum, silver, or an alloy thereof, for example. Alternatively, the wiring patterns 8 and 9 may be each a multi-layer film of layers containing the metal material(s) described above. The dopant in this case preferably contains the metal material(s) in the wiring pattern 8 and 9, or a compound of the metal material(s).

The organic TFT of FIG. 3 is in the configuration similar to that of the organic TFT of FIG. 1 except that the organic TFT of FIG. 3 additionally includes wiring patterns 10 and 11, which are provided separately from each other. The wiring pattern 10 is connected to the upper and side surfaces of the source electrode section 5, for example. The wiring pattern 11 is connected to the upper and side surfaces of the drain electrode section 6, for example. The details about the material and configuration of these wiring patterns 10 and 11 are similar to those of the wiring patterns 8 and 9, for example.

### [1-2. Method of Manufacturing Thin-Film Transistor]

Next, described is a method of manufacturing the organic TFT described above. FIGS. 4 to 6 are for illustrating the method of manufacturing the organic TFT, and each show the cross-sectional configuration thereof corresponding to FIG. 1. Note that the materials of the components in the organic TFT have been described in detail above, and thus the description in the below is given with an example of each material.

In manufacturing the organic TFT, first of all, as shown in FIG. 4, the gate electrode 2 is formed on the support base 1 being a plastic film, for example. In this case, a metal material layer (not shown) is so formed as to cover the surface of the support base 1, and the metal material layer is then subjected to patterning, for example.

The metal material layer is made of copper, for example. Moreover, the metal material layer is formed by gas phase growth method such as sputtering, vapor deposition, and chemical vapor deposition (CVD), for example, and the patterning to be performed thereto is exemplified by etching. This etching may be dry etching including ion milling, reactive ion etching (RIE), or others, or may be wet etching.

For patterning of the metal material layer, photolithography or ultraviolet rendering may be used together therewith, for example. If this is the case, a photoresist film (not shown) is formed on the surface of the metal material layer by coating of a photoresist thereto, for example. Thereafter, the photoresist film is subjected to patterning (light exposure and developing) by photolithography or others, and then using the resulting photoresist film as a mask, the metal material layer is subjected to etching. As an alternative to the photoresist film, a metal film or others may be used as a mask.

Thereafter, the gate insulating layer 3 is formed so as to cover at least the gate electrode 2. This gate insulating layer 3 is made of PVP, for example, and is formed by coating such as spin coating.

Thereafter, on the gate insulating layer 3, the organic semiconductor layer 12 is formed. This organic semiconductor layer 12 is a preprocessing layer for formation of the organic semiconductor section 4, and the source electrode section 5 and the drain electrode section 6. The organic semiconductor layer 12 is made of a p-type channel-use organic semiconductor material such as pentacene. The organic semiconductor layer 12 is formed by (1) gas phase growth method such as resistance heating deposition, sputtering, vacuum deposition, and CVD, or (2) liquid phase growth method such as coating, immersion, and printing. The coating is exemplified by spin coating, air doctor coater, blade coater, rod coater, knife coater, squeeze coater, reverse roll coater, transfer roll coater, gravure coater, kiss coater, cast coater, spray coater, slit orifice coater, or calendar coater. These methods are arbitrarily selected according to the material of the organic semiconductor layer 12, for example. Herein, the thickness of the organic semiconductor layer 12 is not specifically restrictive, and is about 50 nm, for example.

Thereafter, a mask 13 is formed on a part of the organic semiconductor layer 12. In this case, a photoresist film (not shown) is formed on the surface of the organic semiconductor layer 12 by coating of a photoresist thereto, for example. The photoresist film is then subjected to patterning by photolithography or others. Moreover, the area for forming the mask 13 is adjusted to allow patterning of the organic semiconductor layer 12 in any desired size, for example. The material of the mask 13 is not restricted to the photoresist, and any other material (organic or inorganic material) may be used.

Thereafter, the organic semiconductor layer 12 is selectively removed using the mask 13, and the resulting organic semiconductor layer 12 is subjected to patterning. This thus leaves, as shown in FIG. 5, the part of the organic semiconductor layer 12 corresponding to the area formed with the mask 13. Such patterning is dry etching including ion milling, for example, and in this example, the mask 13 is used as an etching mask.

Thereafter, the mask 13 is selectively removed, and the resulting mask 13 is subjected to patterning, for example. This leaves a part of the mask 13 as shown in FIG. 6. In this case, a developing process is performed after additional light exposure to the mask 13 by photolithography, and the mask 13 is left on the organic semiconductor layer 12 at a portion corresponding to the area for forming the organic semiconductor section 4, for example. Herein, instead of the additional light exposure to the mask 13 in use for patterning of the organic semiconductor layer 12, the mask 13 may be removed, and a new mask may be formed in the similar manner.

Lastly, the organic semiconductor layer 12 is subjected to a doping process using the mask 13. To be specific, a dopant D such as iodine (I₂) gas is selectively doped to the organic semiconductor layer 12. In this example, the mask 13 is used as a doping mask. In this doping process, the part of the organic semiconductor layer 12 covered by the mask 13 is not doped with the dopant D, but the part thereof not covered by the mask 13 is doped with the dopant D. As a result, as shown in FIG. 1, by the not-doped part of the organic semiconductor layer 12 (channel-use organic semiconductor material), formed is the organic semiconductor section 4 including he pair of side surfaces M1 and M2. Moreover, by the doped part of the organic semiconductor layer 12 (electrode-use organic semiconductor material higher in conductivity than the channel-use organic semiconductor material), formed are the source electrode section 5 and the drain electrode section 6 respectively adjacent to the side surfaces M1 and M2 of the organic semiconductor section 4.

Alternatively, by the doping process to the organic semiconductor layer 12, only the source electrode section 5 (or the drain electrode section 6) may be formed. If this is the case, by the procedure similar to the method of forming the gate electrode 2, the drain electrode section 6 (or the source electrode section 5) may be formed, for example. Still alternatively, by the procedure similar to a method of forming a drain electrode section 16 (or a source electrode section 15) that will be described later in a second embodiment, the drain electrode section 6 (or the source electrode section 5) may be formed, for example.

Thereafter, the mask 13 is removed by the etching described above or others so that the organic TFT of FIG. 1 is completed. Alternatively, the mask 13 may not be removed but be left as it is. This is since, if the mask 13 is insulative, leaving the mask 13 does not affect the performance of the organic TFT. Note that, in etching the mask 13, attention is expected not to etch unexpectedly down to the organic semiconductor section 4.

### [Function and Effect of Method of Manufacturing Thin-Film Transistor]

With the organic TFT and the manufacturing method thereof, the organic semiconductor layer 12 is partially doped with a dopant D to have the integral structure of the organic semiconductor section 4, and the source electrode section 5 and the drain electrode section 6. As a result, to the side surfaces M1 and M2 of the organic semiconductor section 4, the source electrode section 5 and the drain electrode section 6 are adjacent, which are each a highly-conductive electrode section containing an organic semiconductor material higher in conductivity than the material of the organic semiconductor section 4.

In this case, the source electrode section 5 and the drain electrode section 6 are connected to the active region of the organic semiconductor section 4, and the components, i.e., the organic semiconductor section 4, and the source electrode section 5 and the drain electrode section 6, are all formed by the same type of material (organic material), thereby extremely reducing the contact resistance.

Moreover, the source electrode section 5 and the drain electrode section 6 are formed by the doping process performed to the organic semiconductor layer 12. This accordingly eliminates the process for positional adjustment for overlay of the organic semiconductor section 4, and the source electrode section 5 and the drain electrode section 6. As such, the performance of the organic TFT is less affected by the varying positions of the source electrode section 5 and the drain electrode section 6.

Therefore, the contact resistance is reduced with the use of the active region of the organic semiconductor section 4 as a current path so that the organic TFT is improved in performance. Moreover, the positional adjustment performed in a simplified manner reduces the performance variations among a plurality of organic TFTs so that the production stability is improved. This accordingly improves the performance of the organic TFTs, and the production stability thereof

In particular, with the integral structure of the organic semiconductor section 4 and the source electrode section 5 and the drain electrode section 6, and with no existence of a joint surface between the organic semiconductor section 4 and both the source electrode section 5 and the drain electrode section 6, the contact resistance is reduced to a further degree.

Note here that the similar effect is produced also by forming either the source electrode section 5 or the drain electrode section 6 by doping a part of the organic semiconductor layer 12 with a dopant D.

### 2. SECOND EMBODIMENT/2-1. CONFIGURATION OF THIN-FILM TRANSISTOR

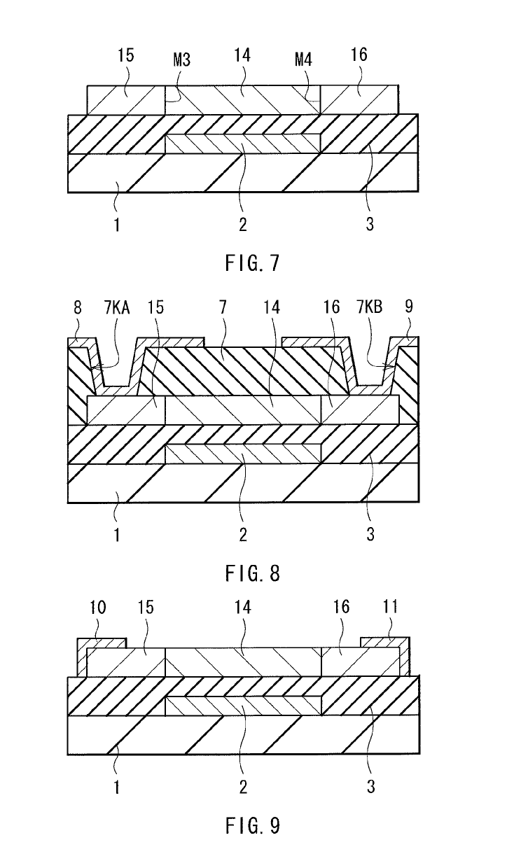

Described next is the configuration of a thin-film transistor according to a second embodiment of the present technology. FIG. 7 shows the cross-sectional configuration of an organic TFT. In FIG. 7 and others subsequent thereto, any component described in the first embodiment is provided with the same reference numeral, and is not described again if appropriate. In the below, the components described in the first embodiment are referred to when appropriate.

The organic TFT in the second embodiment is in the configuration similar to that of the organic TFT in the first embodiment except that it includes an organic semiconductor section 14, a source electrode section 15, and a drain electrode section 16 as alternatives to the organic semiconductor section 4, the source electrode section 5, and the drain electrode section 6, for example. This organic semiconductor section 14 includes a pair of side surfaces M3 and M4 as first and second surfaces, and the source electrode section 15 and the drain electrode section 16 are respectively adjacent to the side surfaces M3 and M4.

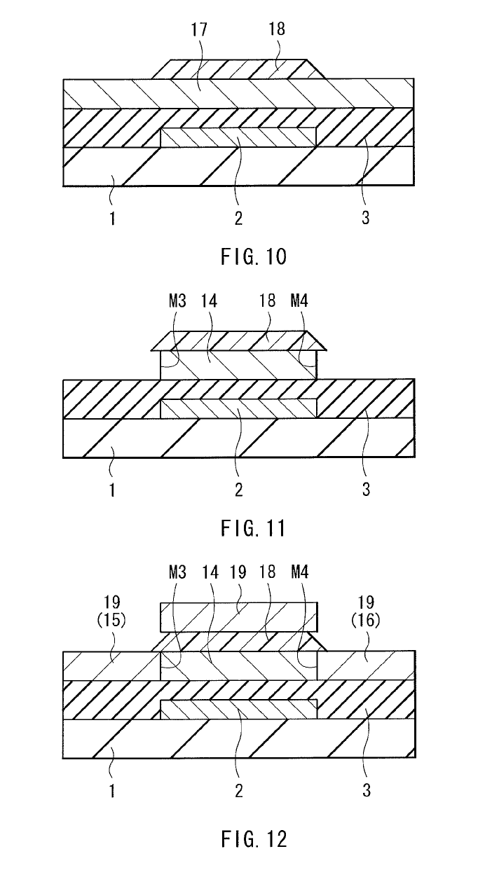

The organic semiconductor section 14 is provided separately from one or both of the source electrode section 15 and the drain electrode section 16, for example. This is since the organic semiconductor section 14 is a portion of an organic semiconductor layer 17 left as it is after the partial removal thereof. The organic semiconductor layer 17 is a preprocessing layer (see FIGS. 10 to 13) as will be described later. To the part where the organic semiconductor layer 17 is removed, one or both of the source electrode section 15 and the drain electrode section 16 are formed thereafter.

In this example, the source electrode section 15 and the drain electrode section 16 are assumed to be formed after the partial removal of the organic semiconductor layer 17, and thus the organic semiconductor section 14 is formed separately from both of the source electrode section 15 and the drain electrode section 16. Accordingly, unlike in the first embodiment, the side surfaces M3 and M4 described above are surfaces (interfaces or junction surfaces) where the organic semiconductor section 14 and the source electrode section 15 and the drain electrode section 16 which are physically separated are in contact. Other than this, the organic semiconductor section 14 is configured similarly to the organic semiconductor section 4, for example.

As described above, the source electrode section 15 and the drain electrode section 16 are formed separately from the organic semiconductor section 14, and are formed in the process different from the process of forming the organic semiconductor section 14 at the position where the organic semiconductor layer 17 (see FIGS. 10 to 13) is removed.

These source electrode section 15 and the drain electrode section 16 are each a highly-conductive electrode section, containing one or two or more of organic semiconductor materials (electrode-use organic semiconductor materials) higher in conductivity than the material of the organic semiconductor section 14, for example. This electrode-use organic semiconductor material may be different from the material forming the organic semiconductor section 14, or may be a mixture of the material forming the organic semiconductor material 14 and a conductive material for increasing the conductivity thereof.

The material different from that of the organic semiconductor section 14 includes a material whose skeleton is not that of the electrode-use organic semiconductor material, or a material including the skeleton same as that of the electrode-use organic semiconductor material with one or two or more of functional groups for increasing the conductivity thereof When the material of the organic semiconductor material 14 is pentacene, the former material is a material other than pentacene, and the latter material is a material being pentacene introduced with a functional group(s), for example.

As to the mixture of the material of the organic semiconductor section 14 and the conductive material, the details about the material of the organic semiconductor section 14 are similar to those about the material of the organic semiconductor section 4, for example, and the details about the conductive material are similar to those about the dopant D, for example.

Note that described above is the case where the source electrode section 15 and the drain electrode section 16 are both formed using the electrode-use organic semiconductor material after the partial removal of the organic semiconductor layer 17, but this is surely not restrictive. Alternatively, one of the source electrode section 15 and the drain electrode section 16 may be formed using the electrode-use organic semiconductor material after the partial removal. The remaining of the source electrode section 15 and the drain electrode section 16 not formed using the electrode-use organic semiconductor material after the partial removal may contain the material similar to that of the gate electrode 2, for example, and may be formed separately from the organic semiconductor section 14. In this case, the source or drain electrode section 15 or 16 may be adjacent to the side surface M3 or M4 of the organic semiconductor section 14, or may be overlaid on the upper or lower side thereof

In this example, as shown in FIGS. 8 and 9 respectively corresponding to FIGS. 2 and 3, the organic TFT may include other components not described above such as the inter-layer insulating layer 7, and the wiring patterns 8 to 11, for example. The conductive material in this case preferably contains a metal material included in the wiring patterns 8 to 11, or a compound of the metal material.

### [2-2. Method of Manufacturing Thin-Film Transistor]

Described next is a method of manufacturing the organic TFT described above. FIGS. 10 to 13 are for illustrating the method of manufacturing the organic TFT, and each show the cross-sectional configuration thereof corresponding to FIG. 7. Note that the materials of the components in the organic TFT have been described in detail above, and thus the description in the below is given with an example of each material. In the below, the components described in the first embodiment are referred to when appropriate.

In manufacturing the organic TFT, first of all, as shown in FIG. 10, the gate electrode 2, the gate insulating layer 3, and the organic semiconductor layer 17 are formed on the support base 1 with the procedure similar to that of the first embodiment except that the organic semiconductor layer 17 is formed as an alternative to the organic semiconductor layer 12. The details about the material of this organic semiconductor layer 17 are similar to those about the material of the organic semiconductor layer 12, for example, and specifically, the material is a peri-xanthenoxanthene derivative expressed by Chemical Formula 1 below, for example. The details about the method of forming the organic semiconductor layer 17 are similar to those about the method of forming the organic semiconductor layer 12, and specifically, the method is vacuum deposition, for example. Herein, the thickness of the organic semiconductor layer 17 is not specifically restrictive, and is about 30 nm, for example.

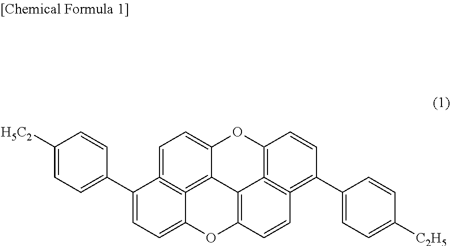

Thereafter, a mask 18 is formed on a part of the organic semiconductor layer 17. The procedure of forming the mask 18 is similar to that of forming the mask 13 except that the formation position of the mask 18 is adjusted to cover the portion mostly serving as the organic semiconductor section 14 on the organic semiconductor layer 17, for example.

Thereafter, the organic semiconductor layer 17 is partially removed using the mask 18, and the resulting organic semiconductor layer 17 is subjected to patterning. This thus leaves, as shown in FIG. 11, the part of the organic semiconductor layer 17 corresponding to the area for forming the mask 18, thereby forming the organic semiconductor section 14 including a pair of side surfaces M3 and M4. Such patterning is dry etching including ion milling, for example, and in this example, the mask 18 is used as an etching mask.

Such patterning not only removes the portion of the organic semiconductor layer 17 not covered by the mask 18 but also slightly removes the portion covered thereby. As a result, the side surfaces M3 and M4 are positioned deeper than both ends of the mask 18.

Thereafter, as shown in FIG. 12, using an organic semiconductor material 19 higher in conductivity than the organic semiconductor section 14 together with the mask 18, the source electrode section 15 and the drain electrode section 16 are formed to the portion where the organic semiconductor layer 17 is removed. In this case, the organic semiconductor material 19 is accumulated also on the mask 18.

The source electrode section 15 and the drain electrode section 16 are made of a mixture of the peri-xanthenoxanthene derivative of Chemical Formula 1, and F4-TCNQ for increasing the conductivity thereof, for example. The source electrode section 15 and the drain electrode section 16 are formed by (1) pas phase growth method such as resistance heating deposition, sputtering, vacuum deposition, and CVD, or (2) liquid phase growth method such as coating, immersion, and printing. The coating is exemplified by spin coating, air doctor coater, blade coater, rod coater, knife coater, squeeze coater, reverse roll coater, transfer roll coater, gravure coater, kiss coater, cast coater, spray coater, slit orifice coater, or calendar coater. These coating methods are arbitrarily selected according to the material of the source electrode section 15 and the drain electrode section 16, for example. Herein, the thickness of the source electrode section 15 and the drain electrode section 16 is not specifically restrictive, and is about 30 nm, for example.

With gas phase growth method, preferably, the material of forming the source electrode section 15 and the drain electrode section 16 is a mixture of the peri-xanthenoxanthene derivative with the F4-TCNQ, and this mixture is accumulated together by co-evaporation, for example. On the other hand, with liquid phase growth method, a solution of the mixture of the peri-xanthenoxanthene derivative with the F4-TCNQ is preferably used for coating or printing, for example. Alternatively, the peri-xanthenoxanthene derivative may be mixed with the F4-TCNQ by first using a solution of the peri-xanthenoxanthene derivative for coating or printing, and before the solution gets dry and fixed, then by using a solution of the F4-TCNQ therefor. This is since, unlike the case of accumulating a low-diffusion inorganic electrode material by sputtering or vapor deposition, if a high-diffusion organic material is accumulated by vapor growth method, or if an organic material is coated by liquid phase growth method, for example, the organic material may reach the underside of the mask 18, and may be easily attached to the side surfaces M3 and M4. Furthermore, since the material of the organic semiconductor section 14 and the material of the source electrode section 15 and the drain electrode section 16 are both organic, this accordingly leads to the close contact between the organic semiconductor layer 14 and the source electrode section 15 and the drain electrode section 16 so that the resulting interface is formed satisfactorily. As a result, the source electrode section 15 and the drain electrode section 16 are respectively adjacent to the side surfaces M3 and M4, thereby reducing the possibility of generating a space between the organic semiconductor layer 14 and both the source electrode section 15 and the drain electrode section 16. What is more, the connection is firmly established between the organic semiconductor layer 14 and both the source electrode section 15 and the drain electrode section 16.

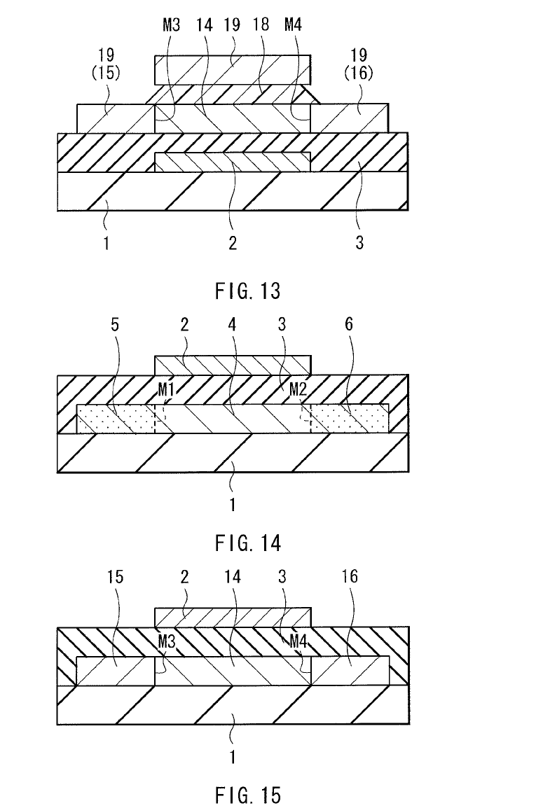

Thereafter, if appropriate, as shown in FIG. 13, the source electrode section 15 and the drain electrode section 16 are partially removed, and the resulting source electrode section 15 and the resulting drain electrode section 16 are subjected to patterning. This patterning is exemplified by laser ablation.

Lastly, the mask 18 is removed (lifted off) together with the organic semiconductor material 19 formed thereon, thereby completing the organic TFT of FIG. 7. Note here that, instead of removing the mask 18 together with the organic semiconductor material 19 thereon, only any unwanted organic semiconductor material 19 may be removed from the mask 18 by dry etching or laser ablation, for example.

Herein, in forming only the source electrode section 15 (or the drain electrode section 16) using the organic semiconductor material 19, the drain electrode section 16 (or the source electrode section 15) may be formed by the procedure similar to that of forming the gate electrode 2, for example.

### [Function and Effect of Method of Manufacturing Thin-Film Transistor]

With the organic TFT and the manufacturing method thereof, after the formation of the organic semiconductor layer 14, the source electrode section 15 and the drain electrode section 16 are formed. The source electrode section 15 and the drain electrode section 16 are each a highly-conductive electrode section, and are formed using the organic semiconductor material 19 higher in conductivity than the material of the organic semiconductor section 14. As a result, the organic semiconductor section 14, and the source electrode section 15 and the drain electrode section 16 are formed separately from one another. In this case, to the side surfaces M3 and M4 of the organic semiconductor section 14, the source electrode section 15 and the drain electrode section 16 higher in conductivity than the organic semiconductor section 14 are adjacent, respectively. Therefore, with the reasons similar to the first embodiment, the contact resistance is reduced, and the performance variations are reduced between the organic TFTs, thereby improving the performance of the organic TFTs and the production stability thereof

In particular, if the source electrode section 15 and the drain electrode section 16 are formed by gas phase growth method, this accordingly leads to the close contact of the source electrode section 15 and the drain electrode section 16, with ease, to the side surfaces M3 and M4 of the organic semiconductor section 14. Accordingly, the contact resistance is reduced to a further degree, and the performance variations of the organic TFTs are reduced to a further degree.

Herein, forming one of the source electrode section 15 and the drain electrode section 16 using the organic semiconductor material 19 may also produce the similar effect.

### 3. MODIFICATION EXAMPLES

As shown in FIG. 14, the organic TFT (see FIG. 1) in the first embodiment may be in the top-gate structure in which the gate electrode 2 is provided on the upper side of the organic semiconductor section 4 (side away from the support base 1). This organic TFT is in the configuration similar to that of the organic TFT of FIG. 1 except that the organic TFT of FIG. 14 includes the organic semiconductor layer 4, the source electrode section 5 and the drain electrode section 6, the gate insulating layer 3, and the gate electrode 2 in this order on the support base 1, for example. Also with the organic TFT of FIG. 14 in the top-gate structure, the similar effect is produced.

Moreover, as shown in FIG. 15, the organic TFT in the second embodiment (see FIG. 7) may be in the top-gate structure in which the gate electrode 2 is provided on the upper side of the organic semiconductor section 14. This organic TFT is in the configuration similar to that of the organic TFT of FIG. 7 except that the organic TFT of FIG. 15 includes the organic semiconductor section 14, the source electrode section 15 and the drain electrode section 16, the gate insulating layer 3, and the gate electrode 2 in this order on the support base 1, for example. Also with the organic TFT of FIG. 15 in the top-gate structure, the similar effect is produced.

### 4. APPLICATION EXAMPLES OF THIN-FILM TRANSISTOR (ELECTRONIC UNITS)

Described next are application examples of an organic TFT being the thin-film transistor described above. This organic TFT is applicable to several types of electronic units as will be described below, for example.

### [4-1. Liquid Crystal Display]

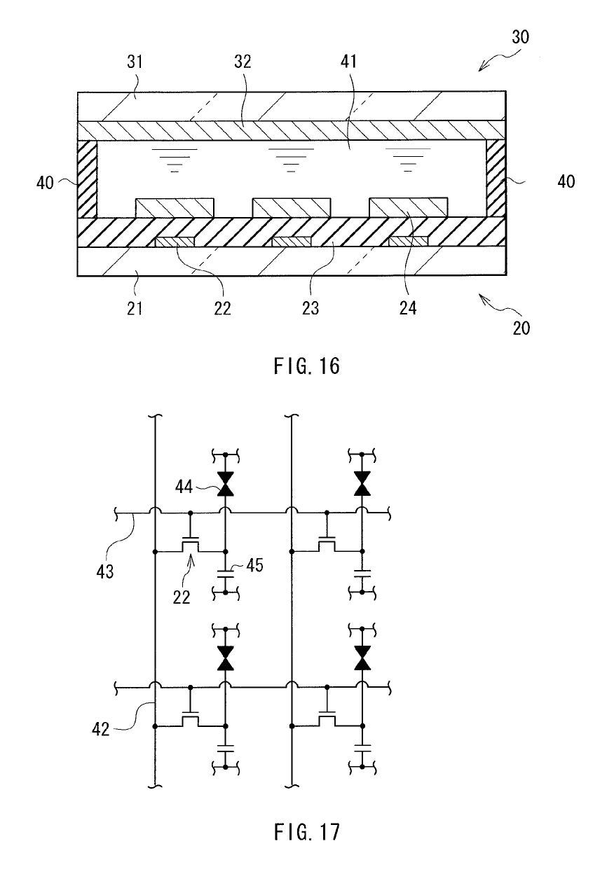

The organic TFT is applied to a liquid crystal display, for example. FIGS. 16 and 17 respectively show the cross-sectional configuration of the liquid crystal display, and the circuit structure thereof Herein, the device structure (FIG. 16) and the circuit structure (FIG. 17) that will be described later are no more than examples, and these structures are thus allowed to be modified as appropriate.

The liquid crystal display herein is an active-matrix transmissive liquid crystal display using organic TFTs, for example. The organic TFTs are each used as switching devices (pixel selection). This liquid crystal display includes a liquid crystal layer 41 sealed between a drive substrate 20 and an opposing substrate 30 as shown in FIG. 16.

The drive substrate 20 includes organic TFTs 22, a planarizing insulating layer 23, and pixel electrodes 24, which are formed in this order on one surface of a support base 21, for example. The organic TFTs 22 and the pixel electrodes 24 are arranged in a matrix. Herein, the number of the organic TFTs 22 in a pixel may be one or two or more. FIGS. 16 and 17 each show a case where one pixel includes one organic TFT 22.

The support base 21 is made of a transmissive material such as glass and a plastic material, and the organic TFT 22 is in the configuration similar to that of the organic TFT described above, for example. The type of the plastic material is similar to the above description given about the organic TFT, for example, and this is applicable also in the following description. The planarizing insulating layer 23 contains an insulating resin material such as polyimide, and the pixel electrode 24 contains a transmissive conductive material such as ITO. Note that the pixel electrode 24 is connected to the organic TFT 22 through a contact hole (not shown) formed to the planarizing insulating layer 23.

The opposing substrate 30 is formed with an opposing electrode 32 entirely on one surface of a support base 31, for example. The support substrate 31 is made of a transmissive material such as glass and a plastic material, and the opposing electrode 32 contains a transmissive conductive material such as ITO.

The drive substrate 20 and the opposing substrate 30 are so disposed that the pixel electrodes 24 and the opposing electrode 32 are opposed to each other with the liquid crystal layer 41 in between. The drive substrate 20 and the opposing substrate 30 are affixed together by a sealing member 40. The type of liquid crystal molecules in the liquid crystal layer 41 is arbitrarily selected.

Other than that, the liquid crystal display may be provided with other components (none is shown) such as a retardation film, a polarizing plate, an alignment film, and a backlight, for example.

The circuit driving the liquid crystal display includes a capacitor 45 together with the organic TFTs 22 and liquid crystal display devices 44 (device section including the pixel electrode 24, the opposing electrode 32, and the liquid crystal layer 41) as exemplarily shown in FIG. 17. In this circuit, a plurality of signal lines 42 are arranged in the row direction, and a plurality of scan lines 43 are arranged in the column direction. At the positions where these signal and scan lines 42 and 43 are intersect, the organic TFTs 22, the organic EL display devices 44, and the capacitors 45 are provided. The connection of the source, gate, and drain electrodes in the organic TFT 22 is not restricted to the state of FIG. 17, and is allowed to be arbitrarily changed. The signal lines 42 and the scan lines 43 are respectively connected to a signal line drive circuit (data driver) and a scan line drive circuit (scan driver) that are not shown.

In this liquid crystal display, when the organic TFT 22 selects the liquid crystal display device 44, and when an electric field is applied between the pixel electrode 24 and the opposing electrode 32, the liquid crystal molecules in the liquid crystal layer 41 are changed in alignment according to the intensity of the electric field. This accordingly controls the amount of light transmission (transmittance) according to the alignment of the liquid crystal molecules so that image display is performed.

With the liquid crystal display, the organic TFT 22 is in the configuration similar to that of the organic TFT described above, thereby improving the performance of the organic TFT 22, and the production stability thereof Accordingly, the display performance and the production stability are improved. Herein, the liquid crystal display is not restricted to be transmissive but reflective.

### [4-2. Organic EL Display]

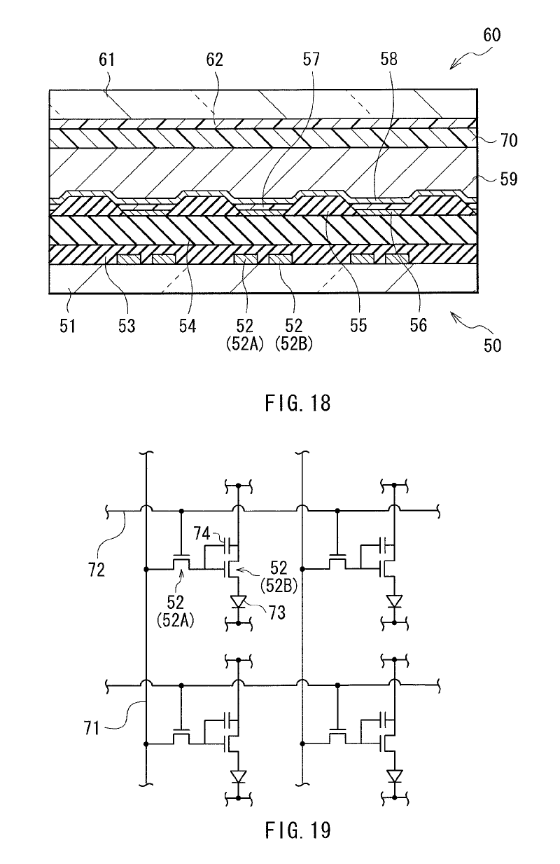

The organic TFT is applied to an organic EL display, for example. FIGS. 18 and 19 respectively show the cross-sectional configuration of the organic EL display, and the circuit structure thereof Herein, the device structure (FIG. 18) and the circuit structure (FIG. 19) that will be described later are no more than examples, and these structures are thus allowed to be modified as appropriate.

The organic EL display herein is an active-matrix organic EL display using organic TFTs as switching devices, for example. This organic EL display includes a drive substrate 50 and an opposing substrate 60 affixed together with an adhesive layer 70 in between, and is in the top-emission structure that emits light via the opposing substrate 60, for example.

The drive substrate 50 includes organic TFTs 52, a protection layer 53, a planarizing insulating layer 54, a pixel separation insulating layer 55, pixel electrodes 56, an organic layer 57, an opposing electrode 58, and a protection layer 59, which are formed in this order on one surface of a support base 51, for example. The organic TFTs 52, the pixel electrodes 56, and the organic layer 57 are arranged in a matrix. Herein, the number of the organic TFTs 52 in a pixel may be one or two or more. FIGS. 18 and 19 each show a case where one pixel includes two organic TFTs 52 (selection TFT 52A, and driving TFT 52B) for example.

The support base 51 is made of glass or a plastic material, for example. With the organic TFT in the top-emission structure, light is extracted from the opposing substrate 60, and thus the support base 51 may be made of either a transmissive material or a non-transmissive material. The organic TFT 52 is in the configuration similar to that of the organic TFT described above, and the protection layer 53 contains a polymeric material such as PVA and poly-para-xylylene. The planarizing insulating layer 54 and the pixel separation insulating layer 55 each contain an insulative resin material such as polyimide. This pixel separation insulating layer 55 preferably contains a photosensitive resin material that is to be shaped by photopatterning, reflowing, or others. This is with the aim of simplifying the manufacturing process, and shaping the pixel separation insulating layer 55 into any desired shape. Herein, if the protection layer 53 provides the sufficient level of flatness, the planarizing insulating layer 54 may not be provided.

The pixel electrode 56 contains a reflective material such as aluminum, silver, titanium, and chromium. The opposing electrode 58 contains a transmissive conductive material such as ITO and IZO. Alternatively, the opposing electrode 58 may contain a transmissive metal material such as calcium (Ca) or an alloy thereof, a transmissive organic conductive material such as PEDOT, or others. The organic layer 57 includes a light-emitting layer that generates light in the color of red, green, or blue, and may be in the multi-layer structure including a hole transport layer, an electron transport layer, or others as appropriate. The material of the light-emitting layer is arbitrarily selected according to the color of light to be generated. The pixel electrodes 56 and the organic layer 57 are arranged in a matrix while being separated by the pixel separation insulating layer 55, but the opposing electrode 58 is formed in a piece and opposing the pixel electrodes 56 via the organic layer 57. The protection layer 59 contains a transmissive dielectric material such as silicon oxide, aluminum oxide, silicon nitride, poly-para-xylylene, and urethane. Herein, the pixel electrode 56 is connected to the organic TFT 52 through a contact hole (not shown) formed to the protection layer 53 and the planarizing insulating layer 54.

The opposing substrate 60 is provided with a color filter 62 on one surface of the support base 61, for example. The support base 61 is formed by a transmissive material such as glass and a plastic material, for example, and the color filter 62 includes a plurality of color regions corresponding to the colors of light generated on the organic layer 57. Note that the color filter 62 is not necessarily provided.

An adhesive layer 70 is an adhesive such as thermosetting resin.

The circuit driving the organic EL display includes a capacitor 74 together with the organic TFTs 52 (the selection TFT 52A and the driving TFT 52B), and organic EL display devices 73 (device section including the pixel electrode 56, the organic layer 57, and the opposing electrode 58) as shown in FIG. 19, for example. In this circuit, at positions where a plurality of signal lines 71 and scan lines 72 are intersect, the organic TFTs 52, the organic EL display devices 73, and the capacitors 74 are disposed. The connection of the source, gate, and drain electrodes to the selection TFT 52A and the driving TFT 52B is not restricted to the state of FIG. 19, and is allowed to be arbitrarily changed.

In this organic EL display, when the selection TFT 52A selects the organic EL display device 73, for example, the organic EL display device 73 is accordingly driven by the driving TFT 52B. In response, when an electric field is applied between the pixel electrodes 56 and the opposing electrode 58, light is generated in the organic layer 57. In this case, in the three organic EL display devices 73 adjacent to each other, the light of red, green, and blue is generated, for example. The combined light of the light in colors is then emitted to the outside via the opposing substrate 60 so that a gray-scale image is displayed.

With the organic EL display, the organic TFT 52 is in the structure similar to that of the organic TFT described above, thereby improving the display performance and the production stability similarly to the liquid crystal display.

Note here that the organic EL display is not restricted to be in the top-emission structure, and may be in the bottom-emission structure that emits light via the drive substrate 50, or in the dual-emission structure that emits light via both the drive substrate 50 and the opposing substrate 60. In this case, either the pixel electrode 56 or the opposing electrode 58 on the light-emitting side is made of a transmissive material, and the remaining electrode not on the light-emitting side is made of a reflective material.

### [4-3. Electronic Paper Display]

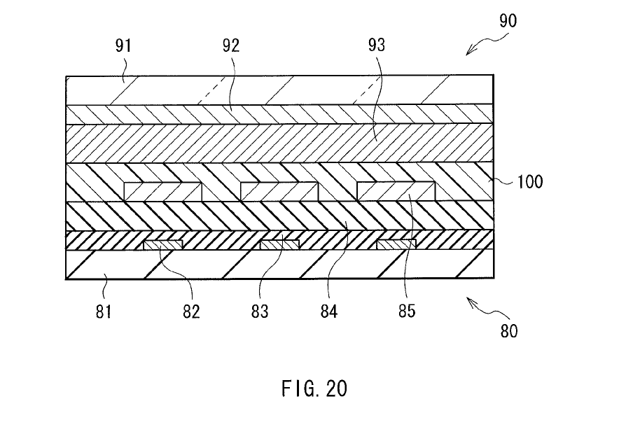

The organic TFT is applied to an electronic paper display, for example. FIG. 20 shows the cross-sectional configuration of an electronic paper display. Note that the device structure (FIG. 20) that will be described below, and the circuit structure that will be described by referring to FIG. 17 are no more than examples, and these structures are allowed to be arbitrarily modified.

The electronic paper display herein is an active-matrix electronic paper display using organic TFTs as switching devices, for example. This electronic paper display includes a drive substrate 80, and an opposing substrate 90 including electrophoretic devices 93, which are affixed together via an adhesive layer 100.

The drive substrate 80 includes organic TFTs 82, a protection layer 83, a planarizing insulating layer 84, and pixel electrodes 85 in this order on one surface of a support base 81. The organic TFTs 82 and the pixel electrodes 85 are arranged in a matrix. The support base 81 is made of glass or a plastic material, for example, and the organic TFT 82 is in the structure similar to that of the organic TFT described above. The protection layer 83 and the flat insulating layer 84 each contain an insulating resin material such as polyimide, and the pixel electrode 85 contains a metal material such as silver. Note that the pixel electrode 85 is connected to the organic TFT 82 through a contact hole (not shown) formed to the protection layer 83 and the planarizing insulating layer 84. Herein, if the protection layer 83 provides the sufficient level of flatness, the planarizing insulating layer 84 may not be provided.

The opposing substrate 90 includes an opposing electrode 92, and a layer including a plurality of electrophoretic devices 93 in this order on one surface of a support base 91, for example. The opposing electrode 92 is formed entirely over the support substrate 91. The support substrate 91 is made of a transmissive material such as glass and a plastic material, and the opposing electrode 92 contains a transmissive conductive material such as ITO. The electrophoretic devices 93 produce contrast utilizing the electrophoretic phenomenon, and the configuration thereof is arbitrary.

Other than that, the electronic paper display may include other components (not shown) such as color filter.

The circuit driving the electronic paper display is in the configuration similar to that of the liquid crystal display of FIG. 17, for example. The circuit of the electronic paper display includes, as alternatives to the organic TFTs 22 and the liquid crystal display devices 44, the organic TFTs 82 and electronic paper display devices (device section including the pixel electrode 85, the opposing electrode 92, and the electrophoretic device 93).

In this electronic paper display, the organic TFT 82 selects the electronic paper display device, and when an electric field is applied between the pixel electrode 85 and the opposing electrode 92, the contrast is produced in the electrophoretic devices 93 in response to the electronic field so that a gray-scale image is displayed.

With the electronic paper display, the organic TFT 82 is in the configuration similar to that of the organic TFT described above, and thus the display performance and the production stability are improved similarly to the liquid crystal display.

While the present technology has been described in detail by referring to the embodiments, the present technology is not restrictive to the embodiments described above, and numerous other modifications may be devised. For example, electronic units for application of the thin-film transistor according to the embodiments of the present technology are not restricted to a liquid crystal display, an organic EL display, or an electronic paper display, and may be applied to any other types of displays. Such other types of displays are exemplified by an MEMS (Micro Electro Mechanical Systems) display section (MEMS display). Also in this case, the display performance is to be improved.

Moreover, the thin-film transistor according to the embodiments of the present technology may be applied to electronic devices other than displays. Such electronic devices are exemplified by a sensor matrix, a memory sensor, an RFID tag (Radio Frequency Identification), or a sensor array. Also in this case, the performance is to be improved.

It is to be noted that the present technology may be configured as follows.

(1) A thin-film transistor, including:

an organic semiconductor section including first and second surfaces;

a source electrode section adjacent to the first surface; and

a drain electrode section adjacent to the second surface, wherein

one or both of the source electrode section and the drain electrode section are highly-conductive electrode sections containing an organic semiconductor material higher in conductivity than a material of the organic semiconductor section.

(2) The thin-film transistor according to (1), wherein

the first and second surfaces are a pair of side surfaces of the organic semiconductor section.

(3) The thin-film transistor according to (1) or (2), wherein

the highly-conductive electrode section and the organic semiconductor section are configured to be integral, and

a material of the highly-conductive electrode section includes a material containing the material of the organic semiconductor material added with an impurity for increasing the conductivity.

(4) The thin-film transistor according to (1) or (2), wherein

the highly-conductive electrode section and the organic semiconductor section are provided separately from each other, and

a material of the highly-conductive electrode section includes a material different from the material of the organic semiconductor section, or a mixture of the material of the organic semiconductor section and a conductive material for increasing the conductivity thereof

(5) The thin-film transistor according to (3), wherein

the highly-conductive electrode section is connected with a wiring pattern containing a metal material, and

the impurity contains the metal material or a compound of the metal material.

(6) The thin-film transistor according to (4), wherein

the highly-conductive electrode section is connected with a wiring pattern containing a metal material, and

the conductive material contains the metal material or a compound of the metal material.

(7) The thin-film transistor according to any one of (1) to (6), wherein

the highly-conductive electrode section and the organic semiconductor section are formed as layers in a same hierarchy level,

a gate electrode is further provided to be positioned via a gate insulating layer from the layers in the same hierarchy level, and

an interface between the gate insulating layer and the layers in the same hierarchy level is in one plane.

(8) A method of manufacturing a thin-film transistor, including:

forming an organic semiconductor layer;

forming an organic semiconductor section by an addition of an impurity to a part of the organic semiconductor layer for increasing conductivity, and forming one or both of a source electrode section and a drain electrode section, the organic semiconductor section including first and second surfaces, the source electrode section being adjacent to the first surface, and the drain electrode section being adjacent to the second surface; and

using one or both of the source electrode section and the drain electrode section as highly-conductive electrode sections, the highly-conductive electrode section containing an organic semiconductor material higher in conductivity than a material of the organic semiconductor section.

(9) A method of manufacturing a thin-film transistor, including:

forming an organic semiconductor section including a first surface and a second surface; and

forming one or both of a source electrode section and a drain electrode section using an organic semiconductor material higher in conductivity than a material of the organic semiconductor section, the source electrode section being adjacent to the first surface, and the drain electrode section being adjacent to the second surface.

(10) The method according to (8), wherein

the first and second surfaces are a pair of side surfaces of the organic semiconductor section.

(11) The method according to (9), wherein

the first and second surfaces are a pair of side surfaces of the organic semiconductor section.

(12) The method according to (8) or (10), wherein

one or both of the source electrode section and the drain electrode section being the highly-conductive electrode sections are connected with a wiring pattern containing a metal material, and

the impurity contains the metal material or a compound of the metal material.

(13) The method according to (9) or (11), wherein

a material different from the material of the organic semiconductor section, or a mixture of the material of the organic semiconductor section and a conductive material for increasing the conductivity thereof is used to form one or both of the source electrode section and the drain electrode section,

one or both of the source electrode section and the drain electrode section are connected with a wiring pattern containing a metal material, and

the conductive material contains the metal material or a compound of the metal material.

(14) The method according to any one of (8), (10), and (12), wherein

one or both of the source electrode section and the drain electrode section and the organic semiconductor section are formed as layers in a same hierarchy level, the source electrode section and the drain electrode section being highly-conductive electrode sections,

a gate electrode is further provided to be positioned via a gate insulating layer from the layers in the same hierarchy level, and

an interface between the gate insulating layer and the layers in the same hierarchy level is in one plane.

(15) The method according to any one of (9), (11), and (13), wherein

one or both of the source electrode section and the drain electrode section and the organic semiconductor section are formed as layers in a same hierarchy level,

a gate electrode is further provided to be positioned via a gate insulating layer from the layers in the same hierarchy level, and

an interface between the gate insulating layer and the layers in the same hierarchy level is in one plane.

(16) The method according to any one of (9), (11), (13), and (15), wherein

the source electrode section and the drain electrode section are formed by gas phase growth method or liquid phase growth method.

(17) An electronic unit including a thin-film transistor, the thin-film transistor including:

an organic semiconductor section including first and second surfaces;

a source electrode section adjacent to the first surface; and

a drain electrode section adjacent to the second surface, wherein

one or both of the source electrode section and the drain electrode section are highly-conductive electrode sections containing an organic semiconductor material higher in conductivity than a material of the organic semiconductor section.

The present disclosure contains subject matter related to that disclosed in Japanese Priority Patent Application JP 2011-183986 filed in the Japan Patent Office on Aug. 25, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin-film transistor, comprising:
an organic semiconductor section including first and second surfaces;
a source electrode section adjacent to the first surface; and
a drain electrode section adjacent to the second surface, wherein
one or both of the source electrode section and the drain electrode section are highly-conductive electrode sections containing an organic semiconductor material higher in conductivity than a material of the organic semiconductor section.

2. The thin-film transistor according to claim 1, wherein
the first and second surfaces are a pair of side surfaces of the organic semiconductor section.

3. The thin-film transistor according to claim 1, wherein
the highly-conductive electrode section and the organic semiconductor section are configured to be integral, and
a material of the highly-conductive electrode section includes a material containing the material of the organic semiconductor material added with an impurity for increasing the conductivity.

4. The thin-film transistor according to claim 1, wherein
the highly-conductive electrode section and the organic semiconductor section are provided separately from each other, and
a material of the highly-conductive electrode section includes a material different from the material of the organic semiconductor section, or a mixture of the material of the organic semiconductor section and a conductive material for increasing the conductivity thereof.

5. The thin-film transistor according to claim 3, wherein
the highly-conductive electrode section is connected with a wiring pattern containing a metal material, and
the impurity contains the metal material or a compound of the metal material.

6. The thin-film transistor according to claim 4, wherein
the highly-conductive electrode section is connected with a wiring pattern containing a metal material, and
the conductive material contains the metal material or a compound of the metal material.

7. The thin-film transistor according to claim 1, wherein
the highly-conductive electrode section and the organic semiconductor section are formed as layers in a same hierarchy level,
a gate electrode is further provided to be positioned via a gate insulating layer from the layers in the same hierarchy level, and
an interface between the gate insulating layer and the layers in the same hierarchy level is in one plane.

8. A method of manufacturing a thin-film transistor, comprising:
forming an organic semiconductor layer;
forming an organic semiconductor section by an addition of an impurity to a part of the organic semiconductor layer for increasing conductivity, and forming one or both of a source electrode section and a drain electrode section, the organic semiconductor section including first and second surfaces, the source electrode section being adjacent to the first surface, and the drain electrode section being adjacent to the second surface; and
using one or both of the source electrode section and the drain electrode section as highly-conductive electrode sections, the highly-conductive electrode section containing an organic semiconductor material higher in conductivity than a material of the organic semiconductor section.

9. A method of manufacturing a thin-film transistor, comprising:
forming an organic semiconductor section including a first surface and a second surface; and
forming one or both of a source electrode section and a drain electrode section using an organic semiconductor material higher in conductivity than a material of the organic semiconductor section, the source electrode section being adjacent to the first surface, and the drain electrode section being adjacent to the second surface.

10. The method according to claim 8, wherein
the first and second surfaces are a pair of side surfaces of the organic semiconductor section.

11. The method according to claim 9, wherein
the first and second surfaces are a pair of side surfaces of the organic semiconductor section.

12. The method according to claim 8, wherein
one or both of the source electrode section and the drain electrode section being the highly-conductive electrode sections are connected with a wiring pattern containing a metal material, and
the impurity contains the metal material or a compound of the metal material.

13. The method according to claim 9, wherein
a material different from the material of the organic semiconductor section, or a mixture of the material of the organic semiconductor section and a conductive material for increasing the conductivity thereof is used to form one or both of the source electrode section and the drain electrode section,
one or both of the source electrode section and the drain electrode section are connected with a wiring pattern containing a metal material, and
the conductive material contains the metal material or a compound of the metal material.

14. The method according to claim 8, wherein
one or both of the source electrode section and the drain electrode section and the organic semiconductor section are formed as layers in a same hierarchy level, the source electrode section and the drain electrode section being highly-conductive electrode sections,
a gate electrode is further provided to be positioned via a gate insulating layer from the layers in the same hierarchy level, and
an interface between the gate insulating layer and the layers in the same hierarchy level is in one plane.

15. The method according to claim 9, wherein
one or both of the source electrode section and the drain electrode section and the organic semiconductor section are formed as layers in a same hierarchy level,
a gate electrode is further provided to be positioned via a gate insulating layer from the layers in the same hierarchy level, and
an interface between the gate insulating layer and the layers in the same hierarchy level is in one plane.

16. The method according to claim 9, wherein
the source electrode section and the drain electrode section are formed by gas phase growth method or liquid phase growth method.

17. An electronic unit including a thin-film transistor, the thin-film transistor comprising:
an organic semiconductor section including first and second surfaces;
a source electrode section adjacent to the first surface; and
a drain electrode section adjacent to the second surface, wherein
one or both of the source electrode section and the drain electrode section are highly-conductive electrode sections containing an organic semiconductor material higher in conductivity than a material of the organic semiconductor section.
